(19) United States
(12) Patent Application Publication
(10) Pub. No.: US 2026/0326263 A1
(43) Pub. Date: Oct. 22, 2026

(54) POLISHING PAD DRESSER WITH CONCAVE RIDGE

(71) Applicant: ASAHI DIAMOND INDUSTRIAL CO., LTD., Tokyo (JP)

(72) Inventors: Mitsuru TSUKADA, Chiba (JP); Jun NISHII, Chiba (JP); Ohito CHINO, Chiba (JP); Takuyo CHIBA, Chiba (JP); Hideo SATO, Chiba (JP)

(21) Appl. No.: 19/708,900

(22) Filed: Jun. 16, 2026

Related U.S. Application Data
(63) Continuation of application No. PCT/JP2024/044857, filed on Dec. 18, 2024.

(30) Foreign Application Priority Data
Dec. 20, 2023 (JP) 2023-214658

(51) Int. Cl. B24B 53/017; B24B 37/24

(52) U.S. Cl. CPC B24B 53/017; B24B 37/24

(57) ABSTRACT

A polishing pad dresser includes a base, and a chip disposed on the base. The chip includes a plurality of protrusions having a diamond-surfaced layer. At least one protrusion of the plurality of protrusions includes a tip protruding away from the base, and a plurality of concave ridges extending from the tip.

### CROSS-REFERENCE TO RELATED APPLICATIONS

This application is a continuation application of PCT Application No. PCT/JP2024/044857, filed on Dec. 18, 2024, which claims the benefit of priority from Japanese Patent Application No. 2023-214658, filed on Dec. 20, 2023. The entire contents of the above listed PCT and priority applications are incorporated herein by reference.

### BACKGROUND

The present disclosure relates to a polishing pad dresser and a dressing apparatus that dress the polishing pad of a polishing apparatus for polishing semiconductor wafers or the like.

Japanese unexamined patent publication No. 2018-032745 describes a dresser (conditioner) that dresses (conditions) a polishing pad of a polishing apparatus. This dresser has a base made of stainless steel or the like, and a plurality of chips made of an Si wafer attached onto the base. The chips include a diamond film formed on a plurality of protrusions by a CVD (Chemical Vapor Deposition) process. Such a dresser using chips with a diamond film formed on a plurality of protrusions by a CVD process is called a CVD dresser.

The tips of the plurality of protrusions of the CVD dresser have an acute angle and a uniform height, in comparison with diamond abrasive grains. Therefore, when the resistance between the chips and the polishing pad increases during dressing, vibration of about 0 to 1 kHz called chattering (hereinafter also referred to as “chattering vibration”) is likely to occur in the CVD dresser. When such vibration occurs, dressing is likely to be unstably performed, and the protrusions of the chips might be broken. Note that chattering vibration hardly occurs in an electrodeposited chip, in which a plurality of diamond abrasive grains are fixed by electrodeposition, and in a bond chip, in which the plurality of diamond abrasive grains are fixed by a bond layer (metal bond, vitrified bond, resin bond, or the like).

### SUMMARY

An example polishing pad dresser may include a base, and a chip disposed on the base. The chip may include a plurality of protrusions having a diamond-surfaced layer. At least one protrusion of the plurality of protrusions may include a tip protruding away from the base, and a plurality of concave ridges extending from the tip.

### BRIEF DESCRIPTION OF THE DRAWINGS

FIG. 1 is a schematic perspective view showing an example polishing apparatus.

FIG. 2 is a schematic cross-sectional view showing an example dressing apparatus.

FIG. 3 is a schematic bottom view showing an example polishing pad dresser.

FIG. 4 is a schematic plan view showing the example polishing pad dresser.

FIG. 5 is a cross-sectional view taken along line V-V shown in FIG. 3.

FIG. 6 is a cross-sectional view taken along line VI-VI shown in FIG. 3.

FIG. 7A is a cross-sectional view for illustrating an example method of manufacturing a dresser main body.

FIG. 7B is a cross-sectional view for illustrating the example method of manufacturing the dresser main body.

FIG. 7C is a cross-sectional view for illustrating the example method of manufacturing the dresser main body.

FIG. 8 is a schematic plan view showing another example polishing pad dresser.

FIG. 9 is a schematic plan view showing still another polishing pad dresser.

FIG. 10 is a schematic plan view showing still another polishing pad dresser.

FIG. 11 is an SEM photograph obtained by imaging a working surface of chips of Example and Comparative example.

FIG. 12 is an SEM photograph obtained by imaging the working surface of the chips of Example and Comparative example.

FIG. 13 is a graph showing results of Examples 1 to 3 and Comparative Examples 1 to 3.

### DETAILED DESCRIPTION

In the following description, with reference to the drawings, the same reference numbers are assigned to the same components or to similar components having the same function, and overlapping description is omitted.

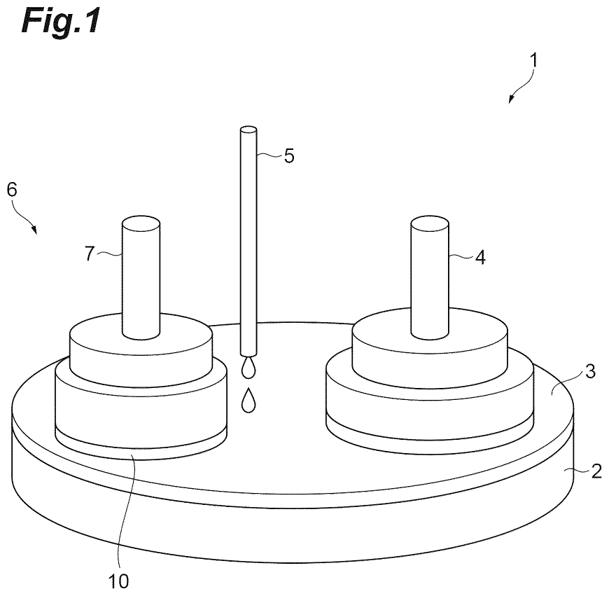

FIG. 1 is a schematic perspective view showing an example polishing apparatus. As shown in FIG. 1, the polishing apparatus 1 may be an apparatus for polishing semiconductor wafers. The polishing apparatus 1 includes a rotatable rotary table 2, a polishing pad 3 disposed on the rotary table 2 and rotating integrally with the rotary table 2, a rotatable polishing head 4 disposed above the polishing pad 3, a nozzle 5 disposed above the polishing pad 3 and supplying slurry or pure water onto the polishing pad 3, and a dressing apparatus 6 for dressing the polishing pad 3. Each of the rotary table 2 and the polishing head 4 is rotationally driven by a driving device (not shown). In the polishing apparatus 1, a semiconductor wafer is attached to a lower end portion of the polishing head 4, the rotary table 2 and the polishing head 4 are rotated, slurry or pure water is supplied from the nozzle 5 onto the polishing pad 3, and the semiconductor wafer is pressed against the polishing pad 3 at a predetermined pressure by the polishing head 4, whereby the semiconductor wafer is polished.

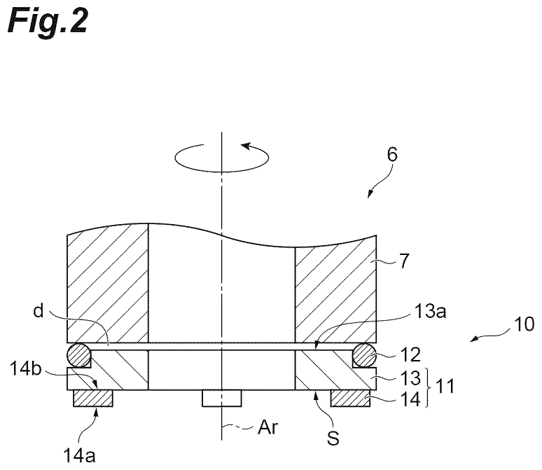

FIG. 2 is a schematic cross-sectional view showing an example dressing apparatus. As shown in FIGS. 1 and 2, the dressing apparatus 6 includes a rotatable dress head 7 disposed above the polishing pad 3, and a polishing pad dresser 10 attached to a lower end portion of the dress head 7. The dress head 7 is rotationally driven by a driving device (not shown).

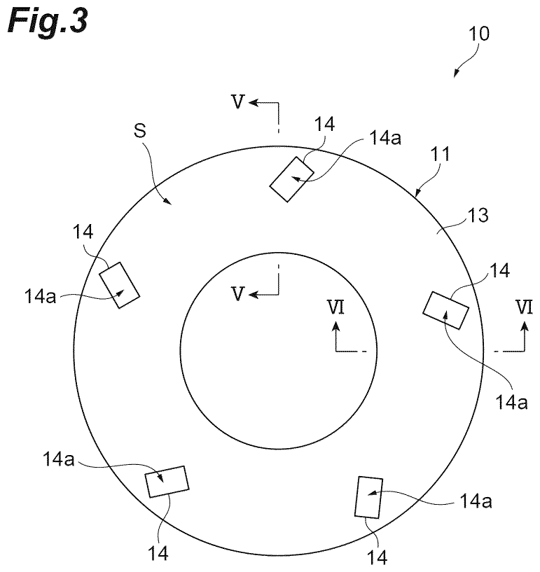

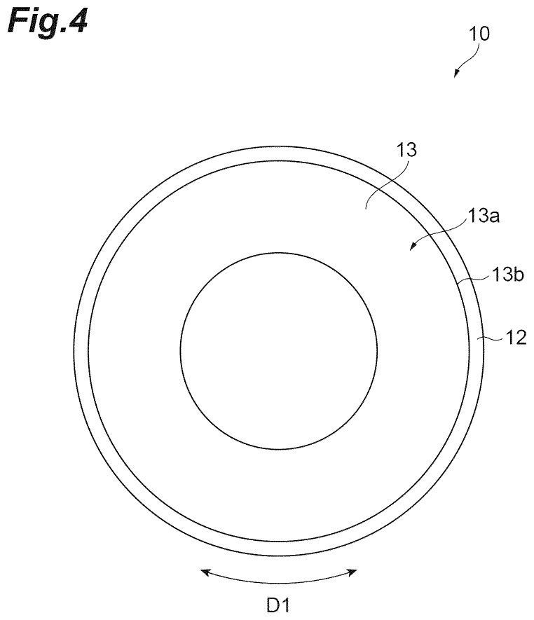

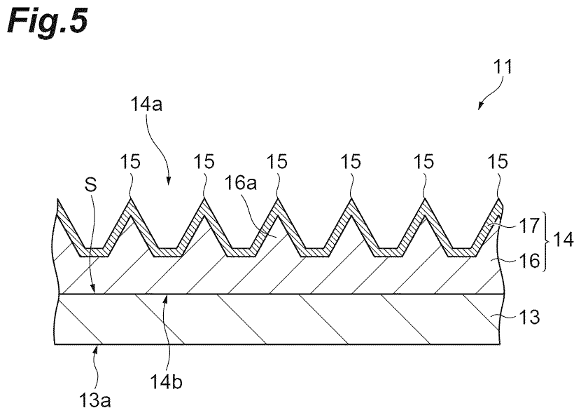

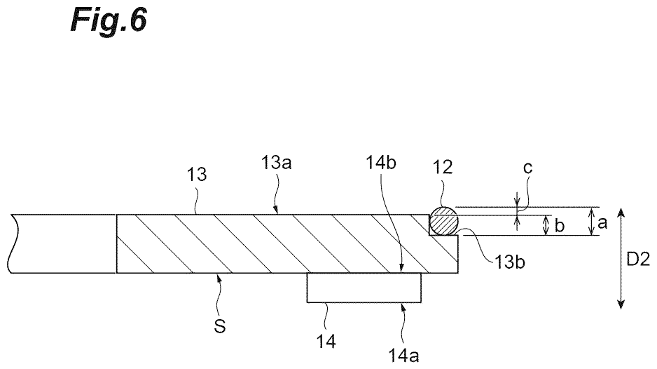

FIG. 3 is a schematic bottom view showing an example polishing pad dresser. FIG. 4 is a schematic plan view showing the polishing pad dresser. FIG. 5 is a cross-sectional view taken along line V-V shown in FIG. 3. FIG. 6 is a cross-sectional view taken along line VI-VI shown in FIG. 3. As shown in FIGS. 2 to 6, the polishing pad dresser 10 includes a dresser main body 11 and an elastic member (elastic body) 12. The dresser main body 11 has an annular base 13 and a plurality of chips 14 disposed on the base 13. The base 13 may be formed of stainless steel (SUS) or the like.

The base 13 includes a first surface and a second surface. The first surface of the base 13 and the second surface of the base 13 are opposite to each other so as to be arranged along a central axis Ar (see FIG. 2) of the base 13, and extend to intersect the central axis Ar. The first surface of the base 13 is a mounting surface 13a (see FIGS. 2 and 4-6) facing the dress head 7. The second surface of the base 13 is a placement surface S (see FIGS. 2, 3, 5, and 6) on which the plurality of chips 14 are disposed. The mounting surface 13a includes a groove 13b into which the elastic member 12 is to be fitted. The groove 13b is formed in a peripheral edge portion of the mounting surface 13a. That is, the groove 13b is formed on the entire circumference along the peripheral edge of the mounting surface 13a to be concentric with the mounting surface 13a. The groove 13b has annular shape and forms the outer peripheral edge of the base 13 at the mounting surface 13a.

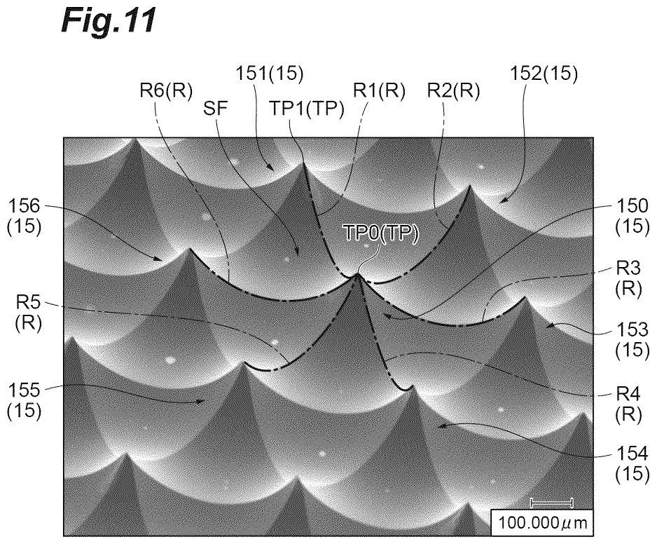

Each of the plurality of chips 14 (hereinafter, simply referred to as “chip 14”) is a member that dresses the polishing pad 3. Each chip 14 includes a first surface and a second surface. The first surface of the chip 14 and the second surface of the chip 14 are opposite to each other. The first surface of the chip 14 is a working surface 14a that dresses the polishing pad 3. The second surface of the chip 14 is an attachment surface 14b that is attached to the base 13. The chip 14 can be attached to the base 13 by, for example, adhesion. The chip 14 includes a plurality of protrusions 15 protruding away from the base 13 and having surfaces formed by a diamond layer 17. The plurality of protrusions 15 are portions that dress the polishing pad 3, and are formed on the working surface 14a. The plurality of protrusions 15 may protrude outwardly from the working surface 14a. The shape of each of the plurality of protrusions 15 is not particularly limited, but can be, for example, a shape with a sharp tip such as a conical shape or a polygonal pyramidal shape. When the protrusion 15 has a polygonal pyramidal shape, the protrusion 15 may include a plurality of concave ridges R (see FIG. 11). Each of the plurality of concave ridges R may extend from a tip TP of the protrusion 15. The tip TP may form an acute angle. Each of the plurality of concave ridges R may have an arcuate shape. The plurality of concave ridges R may extend radially from the tip of the protrusion 15 at substantially equal intervals. The protrusion 15 may have a concave curved surface SF (see FIG. 11). The concave curved surface SF may be disposed between two adjacent concave ridges R of the plurality of concave ridges R. The protrusion 15 may have a hexagonal pyramidal shape, as illustrated in FIG. 11. In this case, the plurality of concave ridges R include six concave ridges R1 to R6. In the example of FIG. 11, the plurality of protrusions 15 may include one protrusion (central protrusion) 150 and six protrusions (peripheral protrusions) 151 to 156 disposed around the protrusion 150 so as to surround the protrusion 150. Each of the six concave ridges R1 to R6 extending from the tip (first tip) TP0 of the protrusion 150 is continuously connected to a respective tip (second tip) of the six protrusions 151 to 156. For example, the concave ridge R1 continuously connects the tip (first tip) TP0 of the protrusion 150 and the tip (second tip) TP1 of the protrusion 151. Therefore, the concave ridge R1 is one of the concave ridges R of the protrusion 150, and is also one of the concave ridges R of the protrusion 151. When the protrusions 15 have a hexagonal pyramidal shape, three concave ridges R extending between respective tips TP of three adjacent protrusions 15 may form a single concave curved surface SF.

The chip 14 includes a substrate 16 and the diamond layer 17 formed on an outer surface of the substrate 16 facing away from the base 13. The outer surface may correspond to the working surface 14a. The substrate 16 is formed of a material containing silicon such as silicon (Si) or silicon carbide (SiC). The substrate 16 includes a plurality of protrusions (a plurality of base protrusions) 16a protruding away from the base 13. The plurality of protrusions 16a of the substrate 16 are portions of the plurality of protrusions 15 of the chip 14 excluding the diamond layer 17. The plurality of protrusions 16a of the substrate 16 may correspond to the plurality of protrusions 15 of the chip 14. While not particularly limited, the shape of each of the plurality of protrusions 16a of the substrate 16 may be similar to that of the plurality of protrusions 15. The diamond layer 17 is formed on the outer surface of the substrate 16. Therefore, the diamond layer 17 is also formed on the plurality of protrusions 16a of the substrate 16. The diamond layer 17 may be formed on the substrate 16 by a CVD process. The diamond layer 17 may be a CVD diamond coating or film. The diamond layer 17 may be formed with a substantially uniform thickness on the outer surface of the substrate 16, that is, on outer surfaces of the plurality of protrusions 16a of the substrate 16.

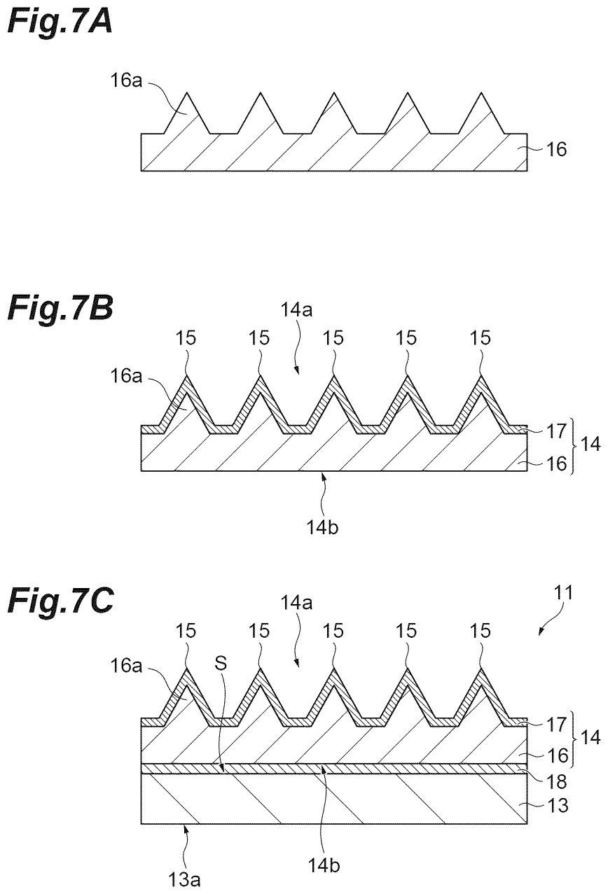

Here, an example of an example method of manufacturing the dresser main body 11 will be described with reference to FIGS. 7A, 7B, and 7C. FIGS. 7A, 7B, and 7C are cross-sectional views for illustrating the example method of manufacturing the dresser main body 11.

First, as shown in FIG. 7A, the substrate 16 having the plurality of protrusions is produced. The substrate 16 having the plurality of protrusions can be produced by, for example, a method described in Japanese unexamined patent publication No. 2018-032745. In this method, first, a wafer made of Si or the like is prepared, and a base layer is formed on the wafer by a CVD process. Next, a resist layer is formed on the base layer, and the resist layer is exposed through a mask. Next, the exposed resist layer is developed, and the base layer and the wafer are etched. The plurality of protrusions 16a are thereby formed on the wafer. Thereafter, by dicing the wafer, the substrate 16 having the plurality of protrusions 16a is obtained.

Next, as shown in FIG. 7B, the diamond layer 17 is formed on the substrate 16 by a CVD process. Examples of the CVD process of forming the diamond layer 17 include a hot filament CVD process and the like. The chip 14 on which the plurality of protrusions 15 are formed is thereby obtained.

Next, as shown in FIG. 7C, the chip 14 is attached to the base 13. The chip 14 can be attached to the base 13 by, for example, adhering the placement surface S and the attachment surface 14b with an adhesive 18. The dresser main body 11 is thereby obtained.

In the dresser main body 11 configured in this manner, a tip of each of the plurality of protrusions 15 of the chip 14 is formed at an acute angle. Further, the tip of each of the plurality of protrusions 15 of the chip 14 is formed at a more acute angle than tips of diamond abrasive grains of an electrodeposited chip and a bond chip.

Further, in the dresser main body 11 configured in this manner, a variation in height of the plurality of protrusions 15 with respect to the base 13 is 0 mm or more and 0.2 mm or less, 0 mm or more and 0.15 mm or less, or 0 mm or more and 0.1 mm or less. This variation can be measured with, for example, a laser microscope.

The elastic member 12 is disposed on the mounting surface 13a facing away from the chip 14. Note that since the chip 14 has the plurality of protrusions 15 protruding away from the base 13 and having the surface formed by the diamond layer 17, the polishing pad dresser 10 has a structure in which chattering vibration is likely to occur with an increase in resistance between the chip 14 and the polishing pad 3 during dressing of the polishing pad 3. Therefore, the polishing pad dresser 10 includes the elastic member 12 disposed on the mounting surface 13a facing away from the chip 14 to attenuate this chattering vibration and suppress the chattering vibration. That is, the elastic member 12 is a member for suppressing this chattering vibration.

From a viewpoint of suppressing chattering vibration, a Shore A hardness of the elastic member 12 is 45 or more and 95 or less, 45 or more and 90 or less, or 45 or more and 85 or less. This Shore A hardness can be measured with, for example, a Shore A durometer.

A material of the elastic member 12 is not particularly limited, but can be, for example, rubber such as nitrile rubber, fluorine rubber, or silicone rubber, resin, or the like.

As shown in FIGS. 2, 4, and 6, the elastic member 12 is formed in an annular shape, and is fitted into the groove 13b formed on the mounting surface 13a of the base 13. Therefore, the elastic member 12 extends in a circumferential direction D1 (see FIG. 4) of the base 13, and is disposed to cover only a part of the mounting surface 13a. The elastic member 12 may cover an outer peripheral edge portion of the base 13 at the mounting surface 13a, and need not cover a central portion of the base 13 at the mounting surface 13a.

As shown in FIG. 6, a thickness (diameter) a of the elastic member 12 may be greater than a depth b of the groove 13b. The elastic member 12 may be configured by, for example, an O-ring having a diameter greater than the depth b of the groove 13b. A protruding length c of the elastic member 12 with respect to the base 13 in a thickness direction D2 of the base 13 when the elastic member 12 is fitted into the groove 13 b may be, for example, 0.1 mm or more and 3 mm or less, 0.1 mm or more and 2 mm or less, or 0.1 mm or more and 1 mm or less. The protruding length c may be a value obtained by subtracting the depth b of the groove 13b from the thickness a of the elastic member 12.

The elastic member 12 may be detachably attached to the base 13, may be non-detachably attached to the base 13, or may be simply disposed opposite the chip 14 relative to the base 13 without being attached to the base 13. The elastic member 12 may be directly or indirectly attached to the base 13.

As shown in FIGS. 1 and 2, the polishing pad dresser 10 configured in this manner is attached to the dress head 7 such that the elastic member 12 is disposed between the dress head 7 of the dressing apparatus 6 and the base 13. At this time, since the thickness a of the elastic member 12 is greater than the depth b of the groove 13b, the dress head 7 and the base 13 are separated. Further, since the elastic member 12 is formed in an annular shape and disposed to cover only a part of the mounting surface 13a, without being disposed on the entire surface of the mounting surface 13a, a gap d is formed between the dress head 7 and the base 13. The polishing pad dresser 10 can be attached to the dress head 7 by, for example, screwing, magnet attraction, or the like.

As described above, in the polishing pad dresser 10, the polishing pad 3 can be dressed by attaching the base 13 to the dress head 7 of the dressing apparatus 6 and rotating the dress head 7. Here, since the chip 14 includes the plurality of protrusions 15 protruding away from the base 13 and having the working surface 14a formed by the diamond layer 17, the polishing pad dresser 10 has a structure in which chattering vibration is likely to occur with an increase in resistance between the chip 14 and the polishing pad 3 during dressing of the polishing pad 3. However, since the elastic member 12 is disposed on the mounting surface 13a of the base 13 facing away from the chip 14, the elastic member 12 is disposed between the dress head 7 and the base 13, and the chattering vibration is attenuated by the elastic member 12. Chattering vibration during dressing can thereby be suppressed.

In this polishing pad dresser 10, since the Shore A hardness of the elastic member 12 is 45 or more and 95 or less, 45 or more and 90 or less, or 45 or more and 85 or less, the polishing pad dresser 10 can be stably attached to the dress head 7, and chattering vibration can be suppressed.

In this polishing pad dresser 10, since the elastic member 12 is made of rubber, chattering vibration can be suppressed.

In this polishing pad dresser 10, since the substrate 16 contains silicon, the plurality of protrusions 15 of the chip 14 can be formed.

In this polishing pad dresser 10, since the tip of each of the plurality of protrusions 15 is formed at an acute angle, the polishing pad dresser 10 has a structure in which chattering vibration is likely to occur when the resistance between the chip 14 and the polishing pad 3 increases during dressing of the polishing pad 3. However, since the elastic member 12 is disposed on the mounting surface 13a of the base 13 facing away from the chip 14, chattering vibration can be suppressed.

In this polishing pad dresser 10, since the variation in height of the plurality of protrusions 15 with respect to the base 13 is 0 mm or more and 0.3 mm or less, 0 mm or more and 0.2 mm or less, or 0 mm or more and 0.1 mm or less, the polishing pad dresser 10 has a structure in which chattering vibration is likely to occur when the resistance between the chip 14 and the polishing pad 3 increases during dressing of the polishing pad 3. However, since the elastic member 12 is disposed on the mounting surface 13a of the base 13 facing away from the chip 14, chattering vibration can be suppressed.

In this polishing pad dresser 10, since the elastic member 12 extends in the circumferential direction D1 of the base 13, the polishing pad dresser 10 can be stably attached to the dress head 7, and chattering vibration can be suppressed.

In this polishing pad dresser 10, since the elastic member 12 is formed in an annular shape, the polishing pad dresser 10 can be stably attached to the dress head 7, and chattering vibration can be suppressed.

In this polishing pad dresser 10, since the groove 13b into which the elastic member 12 is to be fitted is formed on the mounting surface 13a of the base 13 facing away from the chip 14, by fitting the elastic member 12 into the groove 13b, the position of the elastic member 12 with respect to the base 13 can be determined, and the elastic member 12 can be attached to the base 13.

In this polishing pad dresser 10, since the thickness a of the elastic member 12 is greater than the depth b of the groove 13b, chattering vibration can be suppressed by the elastic member 12 even when the elastic member 12 is fitted to a bottom of the groove 13b.

In this polishing pad dresser 10, since the protruding length c of the elastic member 12 with respect to the base 13 in the thickness direction D2 of the base 13 when the elastic member 12 is fitted into the groove 13 b is 0.1 mm or more and 3 mm or less, 0.1 mm or more and 2 mm or less, or 0.1 mm or more and 1 mm or less, the polishing pad dresser 10 can be stably attached to the dress head 7, and chattering vibration can be suppressed.

In this polishing pad dresser 10, since the groove 13b is formed in the peripheral edge portion of the mounting surface 13a, the elastic member 12 can be fitted into the groove 13b. By fitting the elastic member 12 into the groove 13b, the elastic member 12 can be disposed in a wider area, the polishing pad dresser 10 can be stably attached to the dress head 7, and chattering vibration can be suppressed.

In this polishing pad dresser 10, since the elastic member 12 is disposed to cover only a part of the mounting surface 13a of the base 13 facing away from the chip 14, a gap is formed between the dress head 7 and the base 13. Since this facilitates elastic expansion and contraction of the elastic member 12, chattering vibration can be suppressed.

Since the dressing apparatus 6 includes the above-described polishing pad dresser 10, chattering vibration during dressing can be suppressed.

In this dressing apparatus 6, a gap is formed between the dress head 7 and the base 13. Since this facilitates elastic expansion and contraction of the elastic member 12, chattering vibration can be suppressed.

It is to be understood that not all aspects, advantages and features described herein may necessarily be achieved by, or included in, any one particular example. Indeed, having described and illustrated various examples herein, it should be apparent that other examples may be modified in arrangement and detail.

In some examples, the position, the shape, and the like of the groove 13b into which the elastic member 12 is to be fitted need not be particularly limited. The groove 13b may be formed in a region other than the peripheral edge portion of the mounting surface 13a. The groove 13b may have a shape other than an annular shape. The shape and the like of the elastic member 12 need not be particularly limited. The elastic member12 may have a shape other than an annular shape.

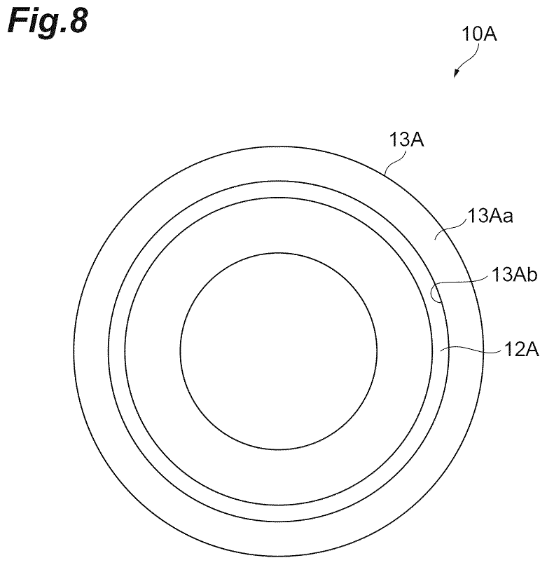

FIG. 8 is a schematic plan view showing another example polishing pad dresser. In a polishing pad dresser 10A shown in FIG. 8, at a position separated from a peripheral edge portion of the mounting surface 13Aa of a base 13A, a groove 13Ab is formed to be concentric with a mounting surface 13Aa. An annular elastic member 12A is fitted into this groove 13Ab.

In the polishing pad dresser 10A, since the groove 13Ab is formed to be concentric with the mounting surface 13Aa at a position separated from the peripheral edge portion of the mounting surface 13Aa, the elastic member 12A can remain fitted into the groove 13Ab. By fitting the elastic member 12A into the groove 13Ab, the polishing pad dresser 10A can be stably attached to the dress head 7, and chattering vibration can be suppressed.

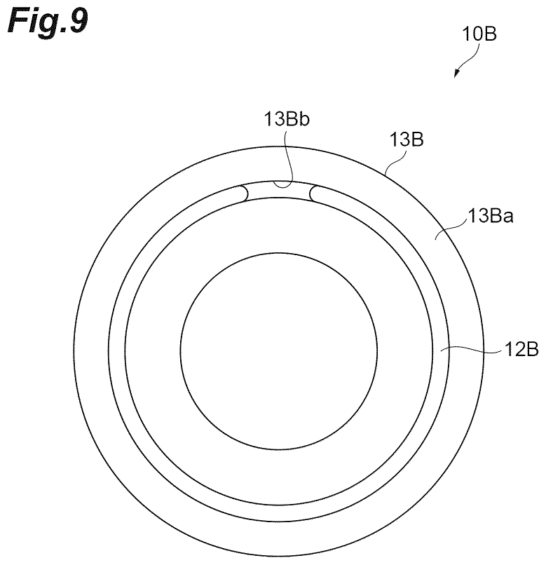

FIG. 9 is a schematic plan view showing still another example polishing pad dresser. In a polishing pad dresser 10B shown in FIG. 9, a groove 13Bb is formed to be concentric with a mounting surface 13Ba at a position separated from a peripheral edge portion of the mounting surface 13Ba of a base 13B. A C-shaped or linear elastic member 12B is fitted into this groove 13Bb.

In the polishing pad dresser 10B, since the groove 13Bb is formed to be concentric with the mounting surface 13Ba at a position separated from the peripheral edge portion of the mounting surface 13Ba, the elastic member 12B can remain fitted into the groove 13Bb. By fitting the elastic member 12B into the groove 13Bb, the polishing pad dresser 10B can be stably attached to the dress head 7, and chattering vibration can be suppressed.

In some examples, the groove 13b need not be formed in the mounting surface 13a as long as the elastic member 12 can be attached to the mounting surface 13a. Similarly, the groove 13Ab need not be formed in the mounting surface 13Aa, and the groove 13Bb need not be formed in the mounting surface 13Ba.

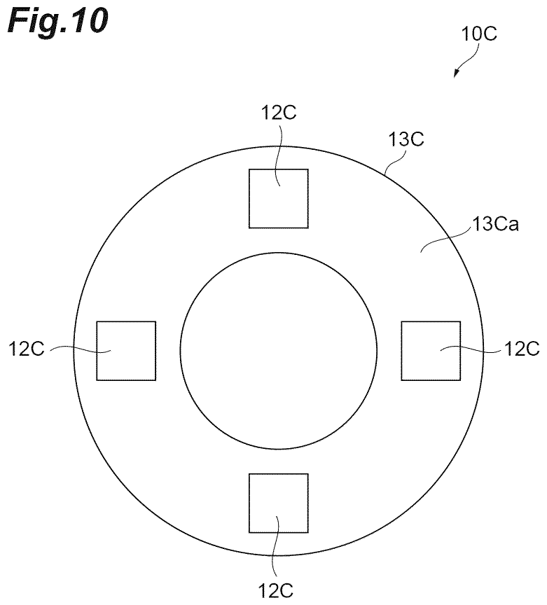

FIG. 10 is a schematic plan view showing still another example polishing pad dresser. In a polishing pad dresser 10C shown in FIG. 10, no groove is formed on a mounting surface 13Ca of a base 13C, and a plurality of rectangular elastic members 12C are adhered to the mounting surface 13Ca. A single annular elastic member may be adhered to the mounting surface 13Ca.

In this way, by adhering the elastic member to the mounting surface, the elastic member can be attached to the mounting surface without forming a groove on the mounting surface.

The elastic member may be formed in a solid shape having no cavity inside, or may be formed in a hollow shape such as a tube having a cavity inside. For example, the elastic members 12, 12A and 12B may be solid members or hollow (tubular) members.

Examples and Comparative examples will be described. Note that the present disclosure is not limited to these Examples and Comparative examples.

### Example 1

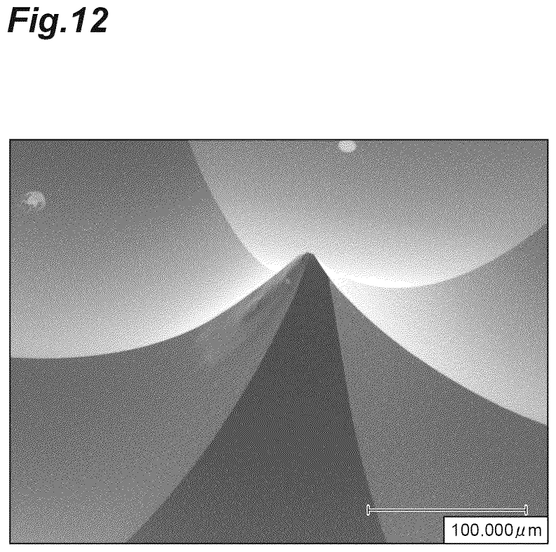

A base layer was formed on a Si wafer by a CVD process, a resist layer was formed on the base layer, and the resist layer was exposed through a mask. Next, the exposed resist layer was developed, the base layer and the Si wafer were etched, and a plurality of protrusions were formed on the Si wafer. Next, by dicing the Si wafer, a plurality of substrates having a plurality of protrusions were produced. Next, by forming a diamond layer on the substrate by a CVD process, a chip having a plurality of protrusions having surfaces formed by the diamond layer was produced. The size of the chip was 6 mm×10 mm. SEM photographs of the produced chip are shown in FIGS. 11 and 12. The SEM photographs shown in FIGS. 11 and 12 are obtained by imaging a working surface of a chip on which a plurality of protrusions are formed. As shown in FIGS. 11 and 12, each of the plurality of protrusions was formed in a hexagonal pyramidal shape having a tip formed at an acute angle. The height of the plurality of protrusions was substantially the same.

Next, a dresser main body was produced by adhering five chips to a base. A groove was formed in a peripheral edge portion of a mounting surface of the base facing away from the chips, and an O-ring as an elastic member was fitted into the groove, to dispose the O-ring on the mounting surface of the base facing away from the chips. The polishing pad dresser of Example 1 was thereby produced. The outer diameter of the base was 101.6 mm, the thickness of the base was 4.3 mm, the depth of the groove was 1.5 mm, and the thickness of the O-ring was 2.0 mm.

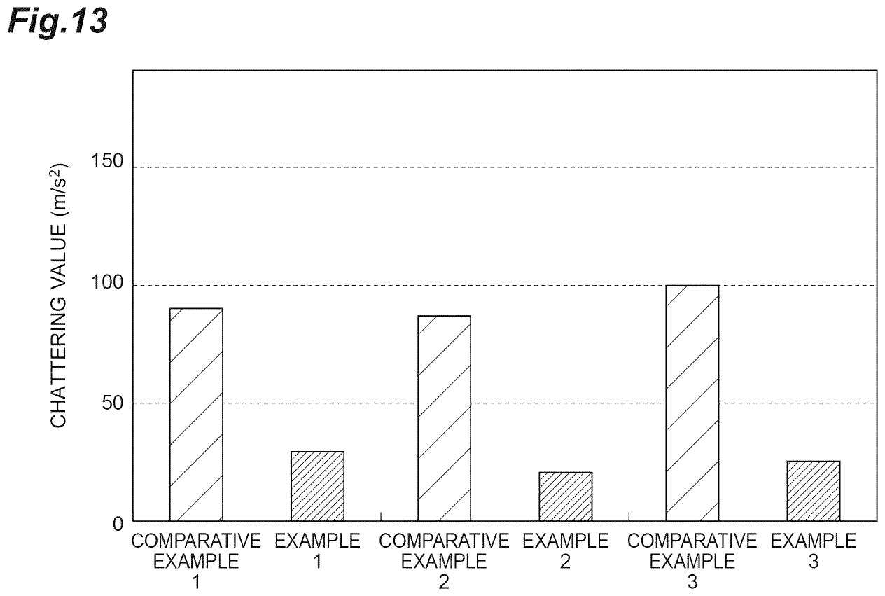

Chattering vibration evaluation was performed using the produced polishing pad dresser of Example 1. In the chattering vibration evaluation, the base was attached to a dress head of a polishing apparatus such that the O-ring was disposed between the dress head and the base, a rotary table and a polishing pad were rotated, the dress head was rotated, slurry was supplied from a nozzle onto the polishing pad, and the chips were pressed against the polishing pad at a predetermined pressure by the dress head, whereby dressing of the polishing pad was performed. The level of chattering vibration during dressing was evaluated. In the evaluation, as a chattering value indicating the level of chattering vibration, a value obtained by integrating vibration acceleration, ranging from 0 kHz to 1 kHz obtained from an acceleration sensor attached to the dress head, was measured. Results are shown in FIG. 13.

### Example 2

A polishing pad dresser of Example 2 was produced under the same conditions as in Example 1 except that seven chips were adhered to the base, and the same chattering vibration evaluation as in Example 1 was performed using the produced polishing pad dresser of Example 2. Results are shown in FIG. 13.

### Example 3

A polishing pad dresser of Example 3 was produced under the same conditions as in Example 1 except that nine chips were adhered to the base, and the same chattering vibration evaluation as in Example 1 was performed using the produced polishing pad dresser of Example 3. Results are shown in FIG. 13.

### Comparative Example 1

A polishing pad dresser of Comparative Example 1 was produced under the same conditions as in Example 1 except that no groove was formed on the mounting surface of the base and no O-ring was used, and the same chattering vibration evaluation as in Example 1 was performed using the produced polishing pad dresser of Comparative Example 1. Note that since the polishing pad dresser of Comparative Example 1 did not use an O-ring, the base was directly attached to the dress head. Results are shown in FIG. 13.

### Comparative Example 2

A polishing pad dresser of Comparative Example 2 was produced under the same conditions as in Example 2 except that no groove was formed on the mounting surface of the base and no O-ring was used, and the same chattering vibration evaluation as in Example 1 was performed using the produced polishing pad dresser of Comparative Example 2. Note that since the polishing pad dresser of Comparative Example 2 did not use an O-ring, the base was directly attached to the dress head. Results are shown in FIG. 13.

### Comparative Example 3

A polishing pad dresser of Comparative Example 3 was produced under the same conditions as in Example 3 except that no groove was formed on the mounting surface of the base and no O-ring was used, and the same chattering vibration evaluation as in Example 1 was performed using the produced polishing pad dresser of Comparative Example 3. Note that since the polishing pad dresser of Comparative Example 3 did not use an O-ring, the base was directly attached to the dress head. Results are shown in FIG. 13.

### Evaluation Results

FIG. 13 is a graph showing results of Examples 1 to 3 and Comparative Examples 1 to 3. As shown in FIG. 13, the chattering value in Examples 1 to 3, in which the O-ring was disposed on the mounting surface of the base facing away from the chips, was significantly smaller than that in Comparative Examples 1 to 3, in which no O-ring was used. In Examples 1 to 3, chattering vibration hardly occurred. It was found from these results that chattering vibration can be suppressed by disposing the O-ring on the mounting surface of the base facing away from the chips.

An example polishing pad dresser may include: a dresser main body including an annular base and a chip disposed on the base; and an elastic member disposed on a side of the base opposite to the chip. The chip may include a plurality of protrusions protruding toward a side opposite to the base and having surfaces formed by a diamond layer.

The polishing pad dresser can dress the polishing pad when the base of the polishing pad dresser is attached on a dress head of a dressing apparatus and the dress head is rotated. Since the chip has the plurality of protrusions protruding toward the side opposite to the base and having the surface formed by the diamond layer, the polishing pad dresser has a structure in which chattering vibration is likely to occur with an increase in resistance between the chip and the polishing pad during dressing of the polishing pad. However, since the elastic member is disposed on the side of the base opposite to the chip, the chattering vibration is attenuated by the elastic member, as the elastic member is disposed between the dress head and the base. Chattering vibration during dressing can thereby be suppressed.

In some examples, a Shore A hardness of the elastic member may be 45 or more and 95 or less. In this polishing pad dresser, since the Shore A hardness of the elastic member is 45 or more and 95 or less, the polishing pad dresser can be stably attached to the dress head, and chattering vibration can be suppressed.

In some examples, the elastic member may be made of rubber. In this dresser for a polishing pad, since the elastic member is made of rubber, chattering vibration can be suppressed.

In some examples, the chip may include a substrate and the diamond layer formed on the substrate. The substrate may contain silicon. In this polishing pad dresser, since the substrate contains silicon, the plurality of protrusions of the chip can be formed.

In some examples, a tip of each of the plurality of protrusions may be formed at an acute angle. In this polishing pad dresser, since the tip of each of the plurality of protrusions is formed at an acute angle, the polishing pad dresser has a structure in which chattering vibration is likely to occur when the resistance between the chip and the polishing pad increases during dressing of the polishing pad. However, since the elastic member is disposed on the side of the base opposite to the chip, chattering vibration can be suppressed.

In some examples, a variation in height of the plurality of protrusions with respect to the base may be 0 mm or more and 0.3 mm or less. In this polishing pad dresser, since the variation in height of the plurality of protrusions with respect to the base is 0 mm or more and 0.3 mm or less, the polishing pad dresser has a structure in which chattering vibration is likely to occur when the resistance between the chip and the polishing pad increases during dressing of the polishing pad. However, since the elastic member is disposed on the side of the base opposite to the chip, chattering vibration can be suppressed.

In some examples, the elastic member may extend in a circumferential direction of the base. In this polishing pad dresser, since the elastic member extends in the circumferential direction of the base, the polishing pad dresser can be stably attached to the dress head, and chattering vibration can be suppressed.

In some examples, the elastic member may be formed in an annular shape. In this polishing pad dresser, since the elastic member is formed in an annular shape, the polishing pad dresser can be stably attached to the dress head, and chattering vibration can be suppressed.

In some examples, a groove into which the elastic member is to be fitted may be formed on a mounting surface of the base on a side opposite to the chip. In this polishing pad dresser, since the groove into which the elastic member is to be fitted is formed on the mounting surface of the base on the side opposite to the chip, by fitting the elastic member into the groove, the position of the elastic member with respect to the base can be determined, and the elastic member can be attached to the base.

In some examples, a thickness of the elastic member may be greater than a depth of the groove. In this polishing pad dresser, since the thickness of the elastic member is greater than the depth of the groove, chattering vibration can be suppressed by the elastic member even when the elastic member is fitted to a bottom of the groove.

In some examples, a protruding length of the elastic member with respect to the base in a thickness direction of the base when the elastic member is fitted into the groove may be 0.1 mm or more and 3 mm or less. In this polishing pad dresser, since the protruding length of the elastic member with respect to the base in the thickness direction of the base when the elastic member is fitted into the groove is 0.1 mm or more and 3 mm or less, the polishing pad dresser can be stably attached to the dress head, and chattering vibration can be suppressed.

In some examples, the groove may be formed in a peripheral edge portion of the mounting surface. In this polishing pad dresser, since the groove is formed in the peripheral edge portion of the mounting surface, the elastic member can be fitted into the groove. Further, by fitting the elastic member into the groove, the elastic member can be disposed in a wider area, the polishing pad dresser can be stably attached to the dress head, and chattering vibration can be suppressed.

In some examples, the groove may be formed to be concentric with the mounting surface at a position separated from the peripheral edge portion of the mounting surface. In this polishing pad dresser, since the groove is formed to be concentric with the mounting surface at the position separated from the peripheral edge portion of the mounting surface, the elastic member can remain fitted into the groove. Further, by fitting the elastic member into the groove, the polishing pad dresser can be stably attached to the dress head, and chattering vibration can be suppressed.

In some examples, the elastic member may be disposed to cover only a part of the mounting surface of the base on a side opposite to the chip. In this polishing pad dresser, since the elastic member is disposed to cover only the part of the mounting surface of the base on the side opposite to the chip, a gap is formed between the dress head and the base. Since this facilitates elastic expansion and contraction of the elastic member, chattering vibration can be suppressed.

An example dressing apparatus may include: a polishing pad dresser; and a rotatable dress head to which the polishing pad dresser is attached. The polishing pad dresser may include: a dresser main body including an annular base and a chip disposed on the base; and an elastic member disposed on a side of the base opposite to the chip. The chip may include a plurality of protrusions protruding toward a side opposite to the base and having surfaces formed by a diamond layer. The polishing pad dresser may be attached to the dress head such that the elastic member is disposed between the dress head and the base. Since this dressing apparatus includes the above-described polishing pad dresser, chattering vibration during dressing can be suppressed.

In some examples, a gap may be formed between the dress head and the base. In this dressing apparatus, the gap is formed between the dress head and the base. Since this facilitates elastic expansion and contraction of the elastic member, chattering vibration can be suppressed.

An example polishing pad dresser may include a base; and a chip disposed on the base. The chip may include a plurality of protrusions having a diamond-surfaced layer. At least one protrusion of the plurality of protrusions may include a tip protruding away from the base, and a plurality of concave ridges extending from the tip.

In some examples, the tip may form an acute angle.

In some examples, the at least one protrusion may include a concave curved surface disposed between two adjacent concave ridges of the plurality of concave ridges.

In some examples, one of the plurality of concave ridges may extend from the tip to a second tip of an adjacent protrusion.

In some examples, the plurality of concave ridges may extend radially from the tip at substantially equal intervals.

In some examples, each of the plurality of protrusions may have a hexagonal pyramidal shape. The plurality of concave ridges may include six concave ridges.

In some examples, the at least one protrusion may be centrally positioned between six peripheral protrusions. Each of the six concave ridges may extend from the tip of the at least one protrusion to a respective tip of the six peripheral protrusions.

In some examples, the chip may include a substrate and the diamond-surfaced layer formed on the substrate. The substrate may contain silicon.

In some examples, a difference of a height of the plurality of protrusions may vary from 0 mm to 0.3 mm.

In some examples, the polishing pad dresser may further include an elastic body disposed on a portion of the base facing away from the chip.

In some examples, the elastic body may be made of rubber.

In some examples, the elastic body may be formed in an annular shape.

In some examples, the base may include a mounting surface facing away from the chip. The mounting surface may include a groove into which the elastic body is fitted.

In some examples, a thickness of the elastic body may be greater than a depth of the groove.

In some examples, a protruding length of the elastic body with respect to the base in a thickness direction of the base when the elastic body is fitted into the groove may vary from 0.1 mm to 3 mm.

In some examples, the groove may be located at, and extends along, an outer peripheral edge of the mounting surface.

In some examples, the groove may be located inward of, and extends along, an outer peripheral edge of the mounting surface.

An example polishing pad dresser may include a base, and a chip disposed on the base. The chip may include a plurality of protrusions having a diamond-surfaced layer. The plurality of protrusions may include a first protrusion including a first tip and a second protrusion including a second tip. The first tip and the second tip may be connected by a concave ridge.

In some examples, the plurality of protrusions may further include a third protrusion including a third tip. The first tip and the third tip may be connected by an adjacent concave ridge.

In some examples, the first protrusion may include a concave curved surface disposed between the concave ridge and the adjacent concave ridge.

What is claimed is:

1. A polishing pad dresser comprising:
a base; and
a chip disposed on the base,
wherein the chip includes a plurality of protrusions having a diamond-surfaced layer, and
wherein at least one protrusion of the plurality of protrusions includes
a tip protruding away from the base, and
a plurality of concave ridges extending from the tip.

2. The polishing pad dresser according to claim 1, wherein the tip forms an acute angle.

3. The polishing pad dresser according to claim 1, wherein the at least one protrusion includes a concave curved surface disposed between two adjacent concave ridges of the plurality of concave ridges.

4. The polishing pad dresser according to claim 1, wherein one of the plurality of concave ridges extends from the tip to a second tip of an adjacent protrusion.

5. The polishing pad dresser according to claim 1, wherein the plurality of concave ridges extend radially from the tip at substantially equal intervals.

6. The polishing pad dresser according to claim 1,
wherein each of the plurality of protrusions has a hexagonal pyramidal shape, and
wherein the plurality of concave ridges include six concave ridges.

7. The polishing pad dresser according to claim 6,
wherein the at least one protrusion is centrally positioned between six peripheral protrusions, and
wherein each of the six concave ridges extends from the tip of the at least one protrusion to a respective tip of the six peripheral protrusions.

8. The polishing pad dresser according to claim 1,
wherein the chip includes a substrate and the diamond-surfaced layer formed on the substrate, and
wherein the substrate contains silicon.

9. The polishing pad dresser according to claim 1, wherein a difference of a height of the plurality of protrusions varies from 0 mm to 0.3 mm.

10. The polishing pad dresser according to claim 1, further comprising an elastic body disposed on a portion of the base facing away from the chip.

11. The polishing pad dresser according to claim 10, wherein the elastic body is made of rubber.

12. The polishing pad dresser according to claim 10, wherein the elastic body is formed in an annular shape.

13. The polishing pad dresser according to claim 10,
wherein the base includes a mounting surface facing away from the chip, and
wherein the mounting surface includes a groove into which the elastic body is fitted.

14. The polishing pad dresser according to claim 13, wherein a thickness of the elastic body is greater than a depth of the groove.

15. The polishing pad dresser according to claim 13, wherein a protruding length of the elastic body with respect to the base in a thickness direction of the base when the elastic body is fitted into the groove varies from 0.1 mm to 3 mm.

16. The polishing pad dresser according to claim 13, wherein the groove is located at, and extends along, an outer peripheral edge of the mounting surface.

17. The polishing pad dresser according to claim 13, wherein the groove is located inward of, and extends along, an outer peripheral edge of the mounting surface.

18. A polishing pad dresser comprising:
a base; and
a chip disposed on the base,
wherein the chip includes a plurality of protrusions having a diamond-surfaced layer,
wherein the plurality of protrusions include a first protrusion including a first tip and a second protrusion including a second tip, and
wherein the first tip and the second tip are connected by a concave ridge.

19. The polishing pad dresser according to claim 18,
wherein the plurality of protrusions further include a third protrusion including a third tip, and
wherein the first tip and the third tip are connected by an adjacent concave ridge.

20. The polishing pad dresser according to claim 19, wherein the first protrusion includes a concave curved surface disposed between the concave ridge and the adjacent concave ridge.
